(19) United States
(12) Patent Application Publication
(10) Pub. No.: US 2009/0096006 A1
(43) Pub. Date: Apr. 16, 2009

(54) NONVOLATILE SEMICONDUCTOR STORAGE APPARATUS AND METHOD FOR MANUFACTURING THE SAME

(75) Inventors: Masayuki TANAKA, Yokohama-shi (JP); Hajime Nagano, Yokkaichi-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/234,150

(22) Filed: Sep. 19, 2008

(30) Foreign Application Priority Data
Sep. 20, 2007 (JP) 2007-243743

(51) Int. Cl. H01L 29/68; H01L 21/336; H01L 29/788

(52) U.S. Cl. 257/316; 438/257; 257/E21.422; 257/E29.17; 257/E29.3

(57) ABSTRACT

According to an aspect of the present invention, there is provided a nonvolatile semiconductor storage apparatus including: a semiconductor substrate on which element isolation trenches are formed to define element formation regions on the semiconductor substrate; gate insulating films that are formed on the element formation regions of the semiconductor substrate; floating gate electrodes that are formed on the gate insulating films; element isolation insulating films that each includes: a coating type insulating film that is formed in a corresponding one of the element isolation trenches; and a non-coating type insulating film that is formed to cover a top surface of the coating type insulating film; a interelectrode insulating film that is formed on the element isolation insulating films and floating gate electrodes; and a control gate electrode that is formed on the interelectrode insulating film.

### CROSS-REFERENCE TO RELATED APPLICATIONS

This application claims priority from Japanese Patent Application No. 2007-243743 filed on Sep. 20, 2007, the entire contents of which are incorporated herein by reference.

### BACKGROUND OF THE INVENTION

1. Field of the Invention

An aspect of the present invention relates to a nonvolatile semiconductor storage apparatus having an element isolation region of a shallow trench isolation (STI) structure, and to a manufacturing method therefor.

2. Description of the Related Art

In recent years, in the technical field of nonvolatile semiconductor storage apparatus, such as flash memory apparatus, an STI structure is formed to divide adjacent gate electrodes. In recent years, with progress in the micropatterning of elements and in reduction in design rule, the aspect ratio of each element isolation region increases. The burying characteristic of element isolation insulating films is deteriorated. A coating film forming technique is proposed as a technique capable of burying such an element isolation region (see, for example, JP-2006-332442-A).

Although a coating type element isolation insulating film formed by the coating film formation technique excels in burying characteristic, the coating type element isolation insulating film is low in density. An interelectrode insulating film is formed on the coating type element isolation insulating film that electrically insulates a floating gate electrode and a control gate electrode from each other. However, components contained in the interelectrode insulating film generate fixed electric charges beside an active region just under a gate insulating film through the inside of a low-density coating type element isolation insulating film and adversely affect the electrical characteristics of a device.

### SUMMARY OF THE INVENTION

According to an aspect of the present invention, there is provided a nonvolatile semiconductor storage apparatus including: a semiconductor substrate on which element isolation trenches are formed to define element formation regions on the semiconductor substrate; gate insulating films that are formed on the element formation regions of the semiconductor substrate; floating gate electrodes that are formed on the gate insulating films; element isolation insulating films that each includes: a coating type insulating film that is formed in a corresponding one of the element isolation trenches; and a non-coating type insulating film that is formed to cover a top surface of the coating type insulating film; a interelectrode insulating film that is formed on the element isolation insulating films and floating gate electrodes; and a control gate electrode that is formed on the interelectrode insulating film.

According to another aspect of the present invention, there is provided a nonvolatile semiconductor storage apparatus including: a semiconductor substrate on which an element isolation trench is formed to define an element formation region; an element isolation insulating film that has a lower portion buried in the element isolation trench and an upper portion protruding from a surface of the semiconductor substrate; a gate insulating film that is formed on the element formation region and that has a side surface contacting a side surface of the upper portion of the element isolation insulating film; a floating gate electrode that is formed on the gate insulating film and that has a top surface, a lower side surface contacting the side surface of the upper portion of the element isolation insulating film, and an upper side surface located above the lower side surface; an interelectrode insulating film that is formed along a top surface of the element isolation insulating film, the upper side surface of the floating gate electrode, and the top surface of the floating gate electrode; and a control gate electrode that is formed on the interelectrode insulating film, wherein element isolation insulating film includes: a coating type insulating film that is formed in the element isolation trench; and a silicon oxide film that is formed to cover a top surface of the coating type insulating film and to isolate the coating type insulating film from the interelectrode insulating film, and wherein silicon oxide film contains 5×10¹⁸ [atoms·cm⁻³] or more of chlorine.

According to still another aspect of the present invention, there is provided a method for manufacturing a nonvolatile semiconductor storage apparatus, the method including: forming a gate insulating film on a semiconductor substrate; forming a floating gate electrode film on the gate insulating film; defining an active region on the semiconductor substrate by forming an element isolation trench to divide the floating gate electrode film, the gate insulating film, and an upper portion of the semiconductor substrate; forming a coating type insulating film in the element insulation trench; forming a silicon oxide film containing 5×10¹⁸ [atoms·cm⁻³] or more of chlorine so as to cover a top surface of the coating type insulating film by use of a chlorine-contained gas; forming an interelectrode insulating film along a top surface of the silicon oxide film, a side surface of the floating gate electrode film, and a top surface of the floating gate electrode film; and forming a control gate electrode film on the interelectrode insulating film.

### BRIEF DESCRIPTION OF THE DRAWINGS

Embodiment may be described in detail with reference to the accompanying drawings, in which:

FIG. 1 is a schematic plan view illustrating the structure of the inside of a nonvolatile semiconductor storage apparatus according to a first embodiment of the present invention;

FIG. 2A is a cross-sectional view taken along a word line direction (cross-sectional view taken along line A-A illustrated in FIG. 1);

FIG. 2B is a cross-sectional view taken along a bit line direction (cross-sectional view taken along line B-B illustrated in FIG. 1);

FIG. 3 is a cross-sectional view (No. 1) schematically illustrating a manufacturing stage;

FIG. 4 is a cross-sectional view (No. 2) schematically illustrating a manufacturing stage;

FIG. 5 is a cross-sectional view (No. 3) schematically illustrating a manufacturing stage;

FIG. 6 is a cross-sectional view (No. 4) schematically illustrating a manufacturing stage;

FIG. 7 is a cross-sectional view (No. 5) schematically illustrating a manufacturing stage;

FIG. 8 is a cross-sectional view (No. 6) schematically illustrating a manufacturing stage;

FIG. 9 is a cross-sectional view (No. 7) schematically illustrating a manufacturing stage;

FIG. 10 is a cross-sectional view (No. 8) schematically illustrating a manufacturing stage;

FIG. 11 is a cross-sectional view (No. 9) schematically illustrating a manufacturing stage;

FIG. 12 is a cross-sectional view (No. 10) schematically illustrating a manufacturing stage;

FIG. 13 is a cross-sectional view (No. 11) schematically illustrating a manufacturing stage;

FIG. 14 is a chart (No. 1) illustrating a threshold value distribution characteristic of a memory cell transistor, which is obtained as a result of an experiment;

FIG. 15 is a chart (No. 2) illustrating a threshold value distribution characteristic of a memory cell transistor, which is obtained as a result of an experiment;

FIG. 16 is a chart illustrating a characteristic of the threshold value distribution of a memory cell transistor with respect to a chlorine content, which is obtained as a result of an experiment;

FIG. 17 is a cross-sectional view (No. 12) schematically illustrating a manufacturing stage according to a second embodiment of the present invention;

FIG. 18 is a cross-sectional view (No. 13) schematically illustrating a manufacturing stage according to the second embodiment;

FIG. 19 is a cross-sectional view (No. 14) schematically illustrating a manufacturing stage according to the second embodiment;

FIG. 20 is a cross-sectional view (No. 15) schematically illustrating a manufacturing stage according to the second embodiment;

FIG. 21 is a cross-sectional view (No. 16) schematically illustrating a manufacturing stage according to the second embodiment;

FIG. 22 is a cross-sectional view (No. 17) schematically illustrating a manufacturing stage according to the second embodiment; and

FIG. 23 is a cross-sectional view (No. 18) schematically illustrating a manufacturing stage according to the second embodiment.

### DETAILED DESCRIPTION OF THE INVENTION

### First Embodiment

Hereinafter, a first embodiment of the present invention, which is applied to a nonvolatile semiconductor storage apparatus, is described with reference to the accompanying drawings. Additionally, in the drawings, which are referred to in the following description, the same or similar parts are designated with the same reference numerals. Incidentally, the drawings are schematic. Thus, the relationship between the thickness and the planar dimension of each part, the ratios among the thicknesses of layers, and the like differ from actual ones.

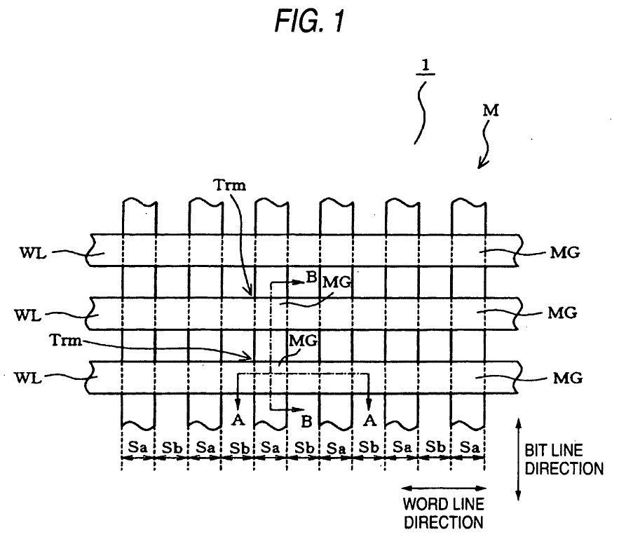

FIG. 1 schematically illustrates a plan view of a memory cell region of a nonvolatile semiconductor storage apparatus. As illustrated in FIG. 1, in a memory cell region M, a large number of memory cell transistors Trm are arranged in a word line direction and a bit line direction. A NAND type flash memory apparatus is cited as a volatile semiconductor storage apparatus having such a memory cell structure in which a plurality of memory cell transistors Trm are series-connected between two selection gate transistors.

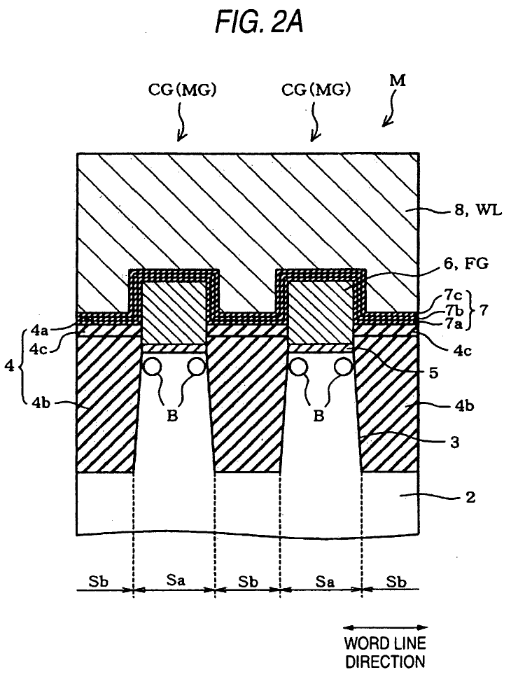

FIG. 2A illustrates a cross-sectional view taken along a word line direction (cross-sectional view taken along line A-A shown in FIG. 1). FIG. 2B illustrates a cross-sectional view taken along a bit line direction (cross-sectional view taken along line B-B shown in FIG. 1).

As illustrated in FIG. 2A, a well (not shown) is formed in an upper part of a p-type silicon substrate 2. A plurality of element isolation trenches 3 are formed in the well. The plurality of element isolation trenches 3 isolate a plurality of active regions Sₐ in a word line direction shown in FIG. 1. Each of element isolation insulating films 4 constituting an element isolation region S_{b} is formed in an associated one of the element isolation trenches 3. Each of element isolation insulating films 4 includes a lower portion buried in the associated element isolation trench 3, and an upper portion upwardly protruding from the surface of the silicon substrate 2.

On the other hand, gate insulating films 5 are formed on each of the active regions Sₐ defined by the element isolation regions S_{b}, respectively. The gate insulating films 5 are formed of, for example, a silicon oxide film. Each of the gate insulating films 5 is such that each of end portions thereof are provided to be contacted with a part of each of upper side surfaces of associated ones of the element isolation insulating films 4. A conductive layer 6 is formed on each of these gate insulating films 5. The conductive layers 6 are formed of, for example, a polysilicon doped with an impurity such as phosphorus, and functions as a floating gate electrode FG, which is an electric charge storage layer.

Each of the conductive layers 6 has a lower side surface put into (surface) contact with an upper side surface of an associated one of the element isolation insulating films 4, and has also an upper side surface upwardly protruding from the top surface 4a of the associated element isolation insulating film 4. The upper side surface of arch of the element isolation insulating films 4, which upwardly projects from the surface of the silicon substrate 2, is formed to be flush with a side surface of the associated gate insulating film 5 and with a lower part of a side surface of an associated one of the gate insulating films 5.

Each of the element isolation insulating films 4 includes a coating type insulating film 4b, and a non-coating type silicon oxide film 4c formed on the coating type insulating film 4b. The non-coating type silicon oxide film 4c includes, for example, a high temperature oxide (HTO) film, a low temperature oxide (LTO) film, and a high density plasma (HDP) film formed by a chemical vapor deposition (CVD) method. The coating type insulating film 4b is constituted by, for example, polysilazane-based spin-on glass (SOG) film and excels in fludity and is good in the burying characteristic, as compared with a tetra ethoxy silane (TEOS) oxide film. The coating type insulating film 4b is constructed so that the top end thereof is positioned above the top surface of the gate insulating film 5.

Each of the HTO films 4c is formed to cover over an associated one of the coating type insulating films 4b. Each of the HTO films 4c is formed so that the bottom thereof is located higher than the top surface of an associated one of the gate insulating films 5, and that the top thereof is located lower than the top surface of an associated one of the conductive layers 6.

The interelectrode insulating film 7 is formed along the top surface of the element isolation insulating film 4 (silicon oxide film 4c), and the upper side surface and the top surface of each of the conductive layers 6. The interelectrode insulating film 7 has a structure in which a silicon nitride film 7a, a high-permittivity insulating film 7b, and a silicon nitride film 7c are deposited in this order from the side of the bottom layer thereof (i.e., from the top surface of the associated element isolation insulating film 4, or the side of the side surface and the top surface of the associated conductive layer 6). For example, an aluminum oxide (Al₂O₃) film having a relative permittivity of about 8 is used as the high-permittivity insulating film 7b.

A conductive layer 8 is formed along the wordline direction on the interelectrode insulating film 7. The conductive layer 8 is formed of a polysilicon, which is doped with an impurity such as phosphorous, and a tungsten silicide layer formed on the polysilicon. The conductive layer 8 serves as a word line WL (including a control gate electrode film and a control gate electrode CG of each memory cell). Thus, each gate electrode MG of the memory cell transistor Trm is constructed by a laminated structure including the conductive layer 6, the interelectrode insulating film 7, and the conductive layer 8.

As illustrated in FIG. 2B, the gate electrodes MG of the memory cell transistors Trm are provided in parallel in the bit line direction. The gate electrodes MG are electrically isolated from one another by dividing regions GV. Although not shown, an interlayer insulating film and a barrier film for restraining impurities from passing therethrough are formed in each dividing region GV.

Source/drain regions 2a are formed on both sides of each gate electrode MG of the memory cell transistor Trm to be placed on the surface layer of the silicon substrate 2. Each of the memory cell transistors Trm includes the gate insulating film 5, the gate electrode MG, and the source/drain region 2a.

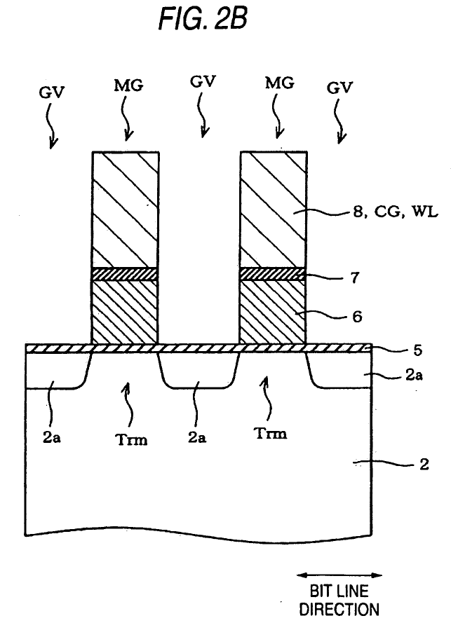

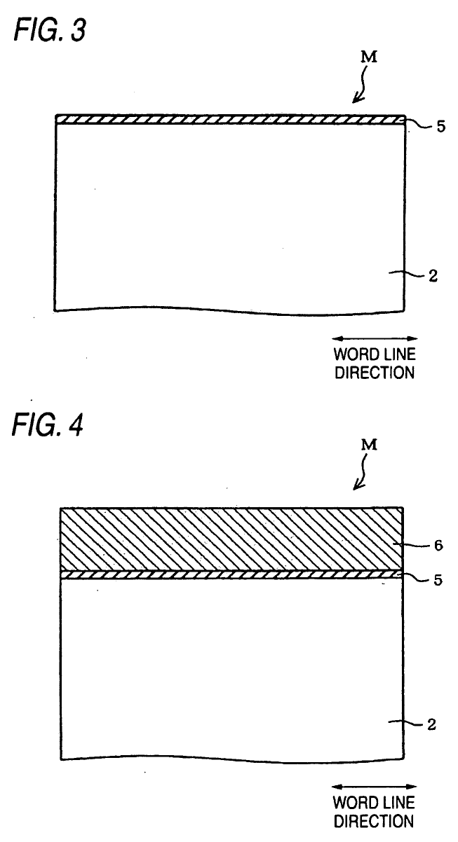

A manufacturing method for the aforementioned apparatus is described with reference to FIGS. 3 to 9.

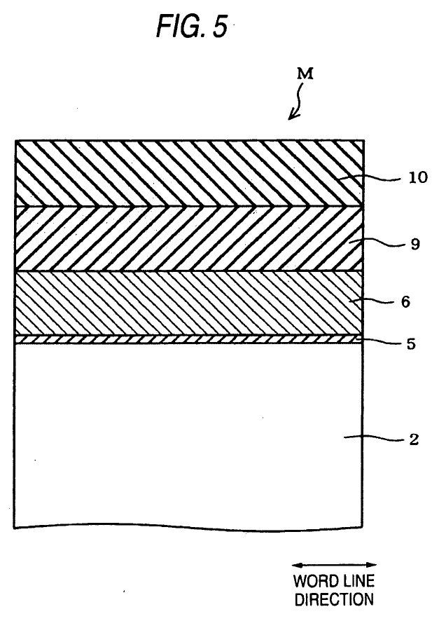

First, as illustrated in FIG. 3, a well structure is formed in an upper portion of the p-type silicon substrate 2. Then, the gate insulating film 5 is formed on the silicon substrate 2. Next, as illustrated in FIG. 4, amorphous silicon is deposited on the gate insulating film 5 by a chemical vapor growth method. This amorphous silicon will be polycrystallized later by a heat treatment and is designated with reference numeral 6. Then, as illustrated in FIG. 5, a silicon nitride film 9 is deposited thereon by the chemical vapor growth method. Next, a silicon oxide film 10 can be deposited thereon by the chemical vapor growth method as a hard mask. Incidentally, the silicon oxide film 10 can be provided as need arises.

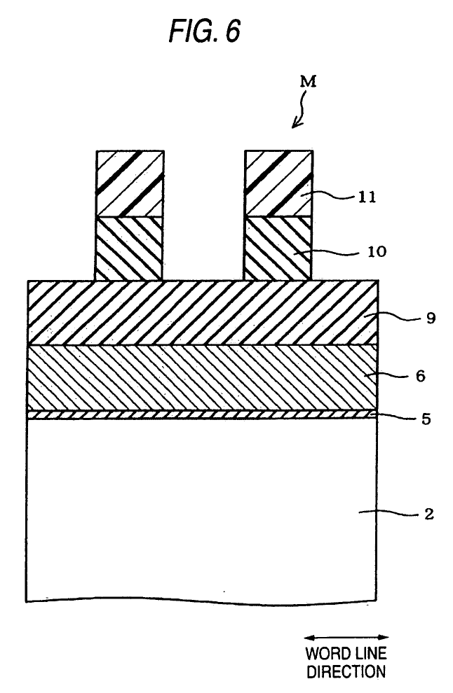

Next, as illustrated in FIG. 6, photoresist is applied onto the silicon oxide film 10. Then, patterning is performed using photolithography techniques. The silicon oxide film 10 is etched by a reactive ion etching (RIE) method using the photoresist 11 as a mask. Upon completion of etching using the RIE method, the photoresist 11 is exfoliated by ashing or the like.

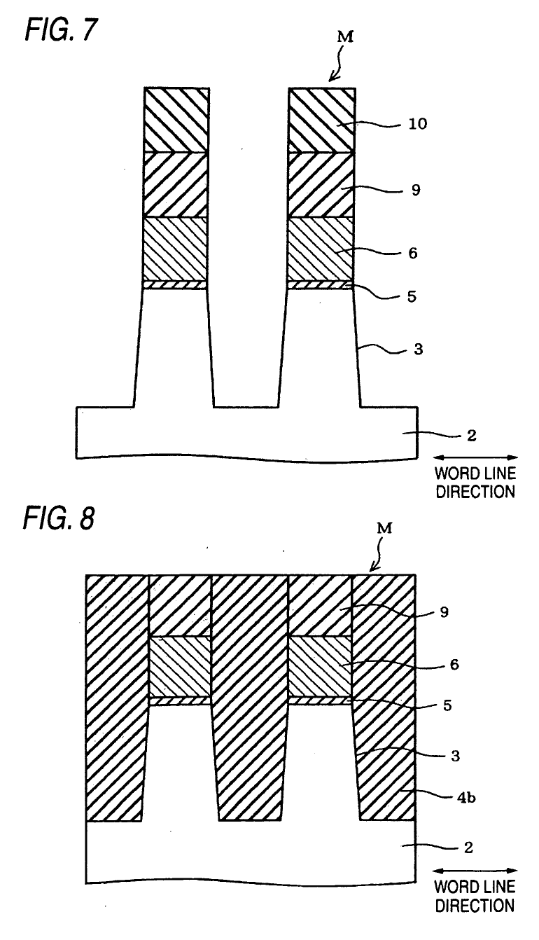

Next, as illustrated in FIG. 7, the silicon nitride film 9 is anisotropically etched by the RIE method using the silicon oxide film 10 as a mask. Then, the conductive film 6, the gate insulating film 5, and an upper portion of the silicon substrate 2 are etched by the RIE method. Consequently, element isolation trenches 3 are formed in the silicon substrate 2.

Next, as illustrated in FIG. 8, a polysilazane-based solvent is applied into each of the element isolation trenches 3 using coating techniques. Then, the polysilazane-based solvent is densified by being subjected to a heat treatment in an oxygen atmosphere or a water-vapor atmosphere. Thus, the applied polysilazane-based solvent is burnt into a coating type insulating film 4b. Next, the coating type insulating film 4b is planarized by a chemical mechanical polishing (CMP) method using the silicon nitride film 9 as a stopper.

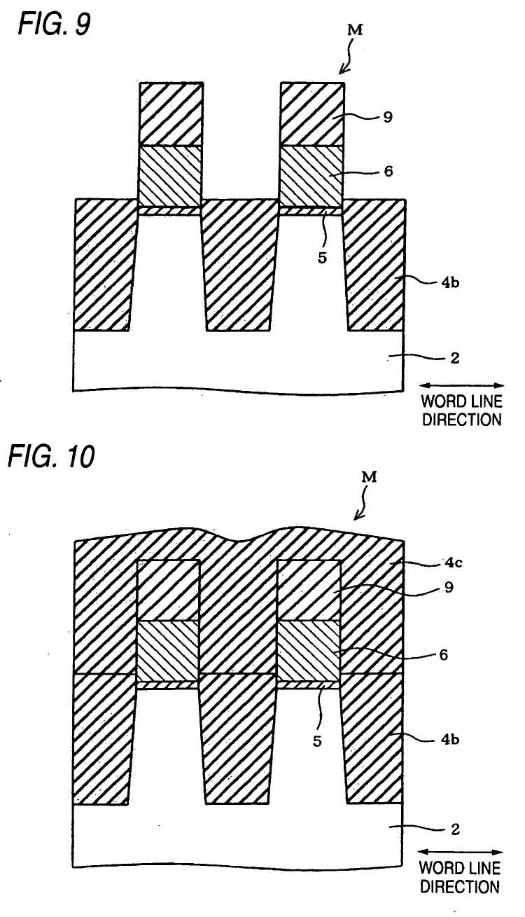

Next, as illustrated in FIG. 9, the coating type insulating film 4b is removed to be higher than the top surface of the silicon substrate 2 and lower than the top surface of the polysilicon layer 6 using a hydrogen fluoride (HF) solution diluted by water.

Next, as illustrated in FIG. 10, a non-coating type silicon oxide film 4c is deposited on the coating type insulating film 4b between the adjacent two conductive layers 6 and 6, and between the adjacent two silicon nitride films 9 and 9. In a case where the HTO film is used as the silicon oxide film 4c, a mixed gas of dichlorosilane (DCS: SiH₂Cl₂) and nitrous oxide (N₂O) is used and reacted under the condition that a temperature is about 800° C. Thus, the HTO film 4c containing chlorine (Cl) is deposited by a low pressure chemical vapor deposition (LP-CVD) method.

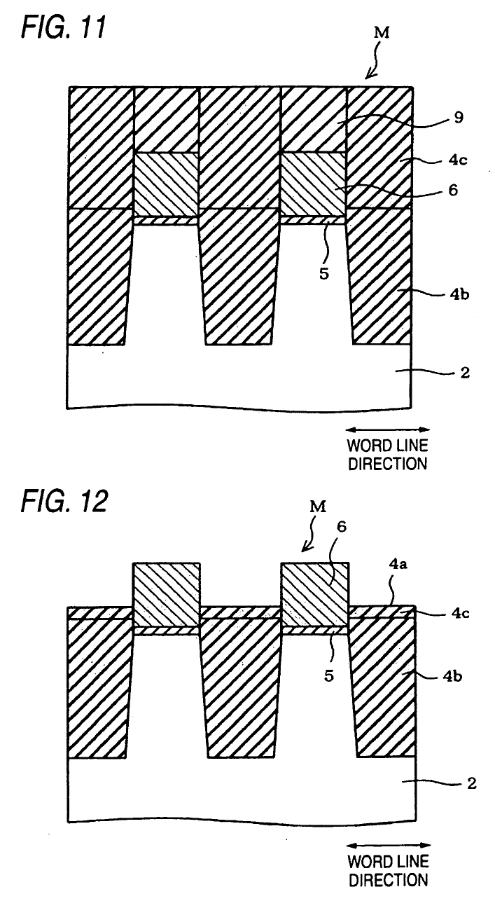

Next, as illustrated in FIG. 11, the silicon oxide film 4c is planarized by the chemical mechanical polishing method using the silicon nitride film 9 as a stopper.

Next, as illustrated in FIG. 12, the silicon oxide film 4c is etched to be lower than the top surface of the polysilicon layer 6 and higher than the top surface of the gate insulating film 5. Then, the silicon nitride film 9 is removed.

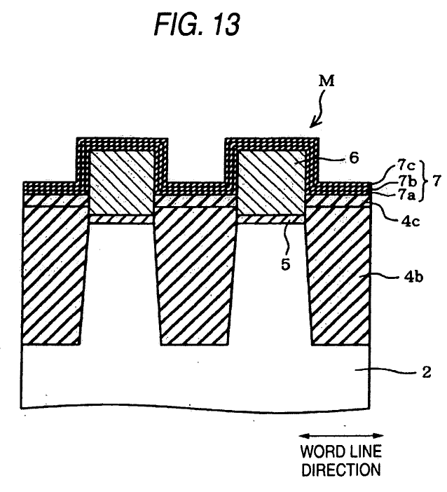

Next, as illustrated in FIG. 13, the silicon nitride film 7a is formed by the LP-CVD method using dichlorosilane (DCS: SiH₂Cl₂) and ammonium (NH₃) under the condition that a temperature is about 800° C. The silicon nitride film 7a is formed along the top surface of the silicon oxide film 4c, and the upper side surface and the top surface of the conductive layer 6. Incidentally, the silicon nitride film 7a can be formed by performing a radical nitridation process under the condition that a temperature is low. Then, an aluminum oxide (Al₂O₃) film 7b having a relative permittivity of about 8 is formed by the LP-CVD method or an atomic layer deposition (ALD) method.

A silicon nitride film (Si₃N₄) has a relative permittivity of about 7. The aluminum oxide film 7b has a relative permittivity of about 8 higher than that of the silicon nitride film (Si₃N₄). It is useful to form the aluminum oxide film 7b to contain oxygen atoms in addition to a metal. Then, the silicon nitride film 7c is formed to cover over the aluminum oxide film 7b. Such a laminate structure, in which the silicon nitride film 7a, the aluminum oxide film 7b, and the silicon nitride film 7c are deposited, is constructed as the interelectrode insulating film 7.

Next, as shown in a cross-sectional view illustrated in FIG. 2A, amorphous silicon doped with an impurity by the CVD method is deposited on the interelectrode insulating film 7. Then, a low resistivity metal silicide layer is formed by sputtering a low resistivity metal onto the amorphous silicon and by performing heat treatment thereon. Thus, the conductive layer 8 is formed by having this laminate structure.

Next, a mask pattern (not shown) is formed on the conductive layer 8. The conductive layer 8, the interelectrode insulating film 7, and the conductive layer 6 are etched along a direction of a plane on which FIG. 2A is drawn, using an anisotropic etching, such as the RIE method. Also, each of the conductive layer 8, the interelectrode insulating film 7, and the conductive layer 6 is divided into a plurality of portions in a direction perpendicular to the plane on which FIG. 2A is drawn. Thus, a structure illustrated in FIG. 2B for dividing the gate electrode MG of the memory cell is obtained.

Next, as illustrated in FIG. 2B, impurities for forming a source/drain region 2a are ion-implanted into the surface layer of the silicon substrate 2 through the dividing regions GV. Subsequently, the barrier film and the interlayer insulating film (any of them are not shown) are deposited thereon. Also, a process for forming contacts in the interlayer insulating films and a process for forming upper layer wirings are performed. The detailed description of the processes is omitted.

Experimental Results

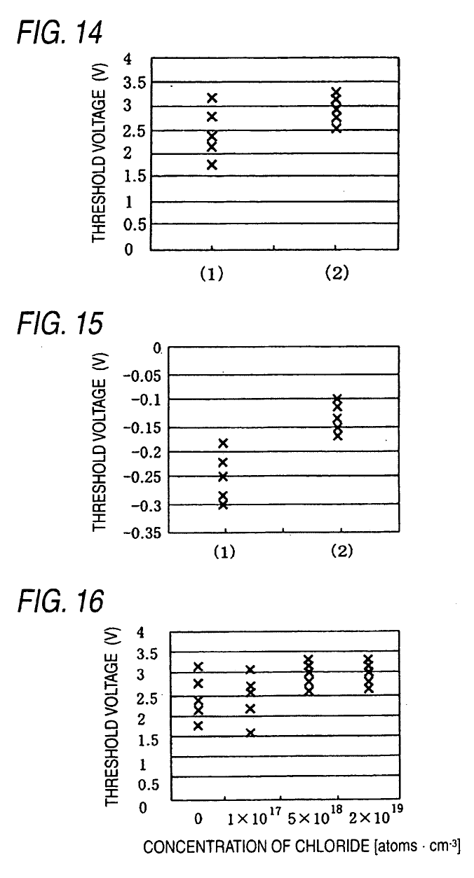

The inventors compare experimental results for a case (1), in which the silicon oxide film 4c is not provided in the element isolation insulating film 4, and for a case (2) in which the silicon oxide film 4c is provided in the element isolation insulating film 4. FIGS. 14 and 15 illustrate the threshold value distributions for the cases (1) and (2). The measurement to acquire the results shown in each of FIGS. 14 and 15 are conducted by use of the same design parameters, such as device dimension, in the both cases (1) and (2). As illustrated in FIG. 14, in the case where the silicon oxide film 4c is not provided in the element isolation insulating film 4, the threshold value ranges from about 1.8 V to about 3.2 V. Thus, variation in the threshold value is equal to or more than 1 [V]. On the other hand, in the case where the silicon oxide film 4c is provided in the element isolation insulating film 4, the threshold value ranges from about 2.6 V to about 3.3 V. Thus, variation in the threshold value is less than 1 [V].

Further, as illustrated in FIG. 15, in the case where the silicon oxide film 4c is not provided in the element isolation insulating film 4, the threshold value ranges from about −0.3 V to about −0.18 V. Thus, variation in the threshold value is equal to or more than 0.1 [V]. On the other hand, in the case where the silicon oxide film 4c is provided in the element isolation insulating film 4, the threshold value ranges from about −0.16 V to about −0.1 V. Thus, variation in the threshold value is less than 0.1 [V].

Usually, the density of the silicon oxide film 4c constituted by the HTO film or the like is equal to or more than 2.2 [g/cm³]. Although it is depends upon a forming method, the density of the coating type insulating film 4b is generally less than 2.2 [g/cm³]. The inventors consider that the low density of the element isolation insulating film 4 causes nitrogen contained in the interelectrode insulating film 7 to generate fixed electric charges in a part located beside an active region just under a gate insulating film through the element isolation insulating film 4 to thereby increase the variation in the threshold value. Accordingly, the embodiment employs the structure described in the foregoing description.

In addition, the inventors find out that it is effective to introduce a chemical-element having a high electronegativity into the silicon oxide film 4c. The inventors have confirmed that the variation in the threshold value can be reduced by causing the silicon oxide film 4c to contain 5×10¹⁸ [cm⁻³] or more of chlorine (Cl).

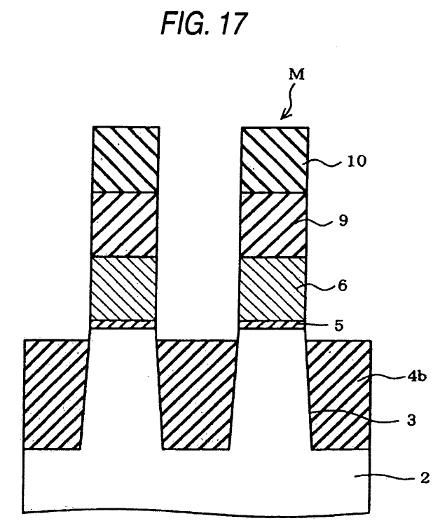

FIG. 16 illustrates experimental data. Here, the same design parameters as used for the case (2) shown in FIG. 14 are used, and the contained amount of chlorine is changed. As illustrated in FIG. 16, even in a case where the silicon oxide film 4c contains chlorine at a concentration of less than 1×10¹⁷ [cm⁻³], the variation in the threshold value ranges from about 1.5 V through 2.0 V and is large (the same level as the case (1) shown in FIG. 14). However, the variation in the threshold value of each of the memory cell transistors Trm can be suppressed to about 1 V or less by causing the silicon oxide film 4c to contain 5×10¹⁸ [cm⁻³] or more of chlorine (the same level as the case (2) shown in FIG. 14). That is, the inventors have confirmed that the variation in the threshold value can be reduced by causing the silicon oxide film 4c to contain 5×10¹⁸ [cm⁻³] or more of chlorine.

According to the first embodiment, the silicon oxide film 4c is formed to cover over the coating type insulating film 4b. Thus, nitrogen can be restrained by the silicon oxide film 4c from entering the coating type insulating film 4b from the silicon nitride films 7a and 7c. Consequently, the embodiment can effectively suppress an amount of fixed electric charge to a low level, which is generated in the active region Sₐ in the surface layer of the silicon substrate 2, more specifically, regions B respectively located on both sides of a portion positioned just under the gate insulating film 5 illustrated in FIG. 2A. Accordingly, the embodiment can effectively restrain variation in the threshold value voltage among the memory cell transistors Trm.

Further, because the silicon oxide film 4c contains 5×10¹⁸ [cm⁻³] or more of chlorine (whose atomic symbol: Cl), the variation in the threshold value can be suppressed low.

In the first embodiment, the top surface of the coating type insulating film 4b is not necessarily positioned higher than the surface of the silicon substrate 2. The top surface of the coating type insulating film 4 can be positioned lower than the surface of the silicon substrate 2.

### Second Embodiment

FIGS. 17 to 23 illustrate a second embodiment of the present invention. The second embodiment differs from the first embodiment in a region in which the silicon oxide film 4c is formed. In FIGS. 17 to 23, component same as or similar to those of the first embodiment is designated with a reference numeral which is same as or similar to those of the first embodiment. Thus, the description of such a component is omitted. Hereinafter, only the differences between the first embodiment and the second embodiment are described.

FIGS. 17 to 23 are cross-sectional views schematically illustrating manufacturing stages, respectively.

As described in the foregoing description of the first embodiment, after the gate insulating film 5, the conductive layer 6, the silicon nitride film 9, and the silicon oxide film 10 are sequentially formed on the p-type silicon substrate 2, the element isolation trenches 3 are formed. Then, a polysilazane-based solvent is applied into each of the element isolation trenches 3. Further, a heat treatment is performed in an oxygen atmosphere or a water-vapor atmosphere to densify the polysilazane-based solvent. Thus, the applied polysilazane-based solvent is burnt into a coating type insulating film 4b. At that time, the coating type insulating film 4b is treated using an HF solution diluted by water to thereby form the coating type insulating film 4b so that the top end thereof is positioned lower than the top surface of the silicon substrate 2.

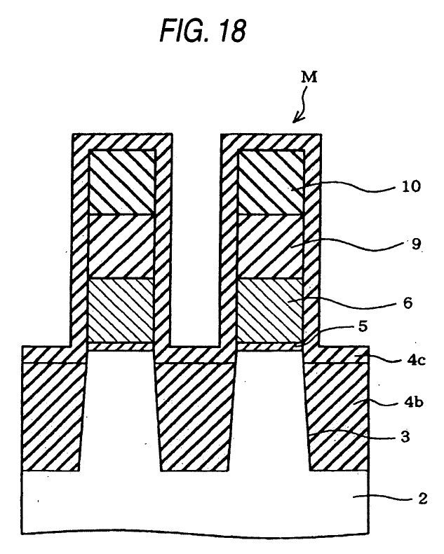

Next, as illustrated in FIG. 18, a silicon oxide film 4c containing chlorine (Cl) is formed by the LP-CVD method along the top surface of the coating type insulating film 4b (the side surface of the gate insulating film 5, and a upper side surface of the element isolation trenches 3), a side surface of the conductive layer 6, a side surface of the silicon nitride film 9, a side surface and the top surface of the silicon oxide film 10. In a case where the silicon oxide film 4c is formed of the HTO film, dichlorosilane (SiH₂Cl₂) and nitrous oxide (N₂O) are made to react under the condition where a temperature is about 800° C.

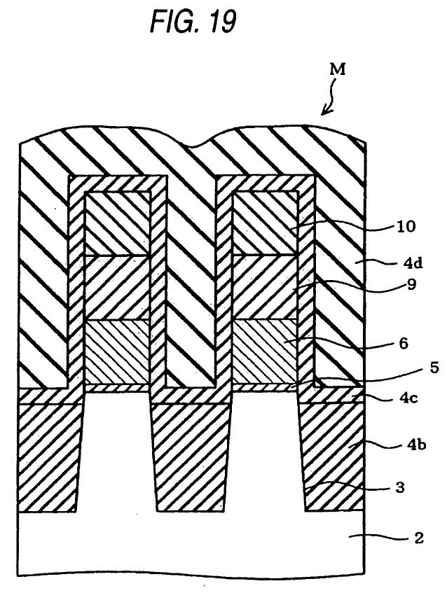

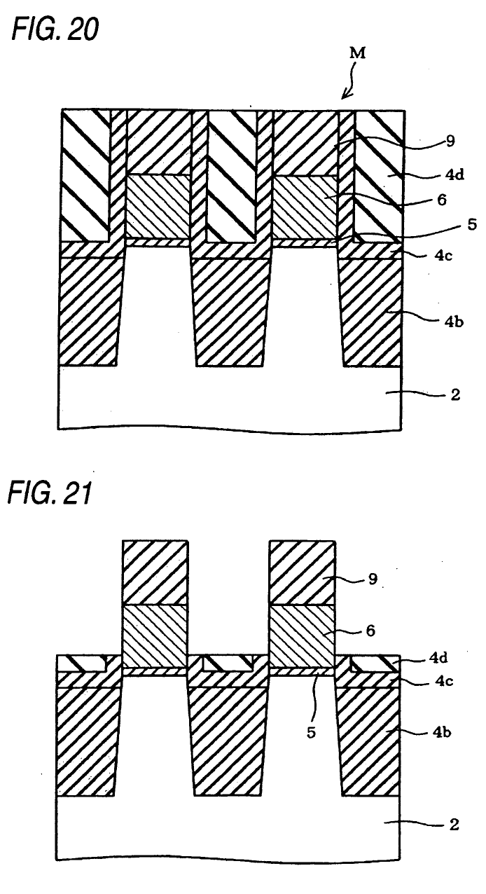

Next, as illustrated in FIG. 19, a polysilazane solution is applied onto the silicon oxide film 4c and is subjected to a heat treatment. Thus, the applied polysilazane solution is burnt into a coating type insulating film 4d. Then, as illustrated in FIG. 20, the coating type insulating film 4d is planarized by the chemical mechanical polishing method (CMP method) using the silicon nitride film 9 as a stopper.

Next, as illustrated in FIG. 21, the silicon oxide film 4c and the coating type insulating film 4d are processed in a condition in which a selectivity for the films 4c and 4d is higher than that for the silicon nitride film 9 so that the top surface of each of the films 4c and 4d is positioned higher than the top surface of the gate insulating film 5 and lower than the top surface of each of the conductive layers 6. Thus, the upper side surface of the polysilicon layer 6 is exposed. Then, the silicon oxide film 4c is constructed to cover the bottom surface and the side surface of the coating type insulating film 4d.

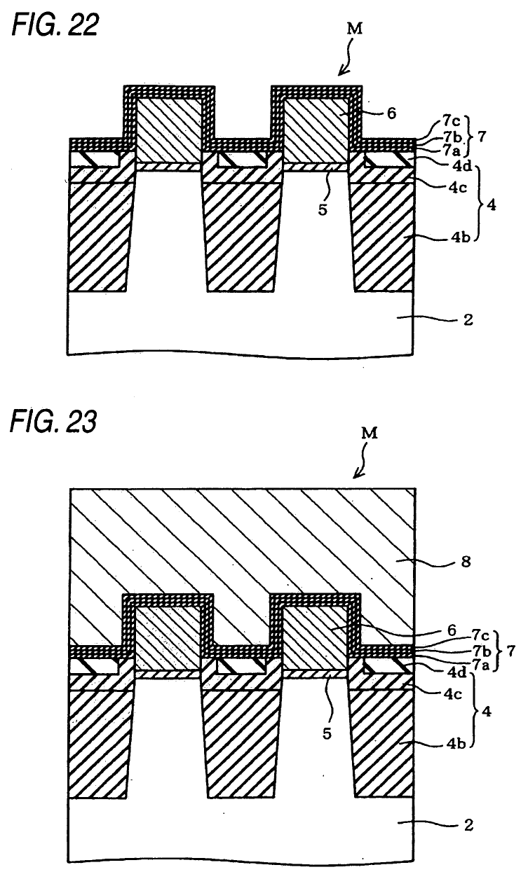

Subsequently, as illustrated in FIG. 22, each of the silicon nitride film 7a, the aluminum oxide film 7b, and the silicon nitride film 7c is formed as the interelectrode insulating film 7 by performing a manufacturing process similar to that performed in the first embodiment. Further, as illustrated in FIG. 23, the conductive layer 8 is formed on the interelectrode insulating film 7. Thus, the laminated films 6 to 8 (and the gate insulating film 5, if necessary) are divided into a plurality of portions. A process subsequent thereto is omitted.

According to the second embodiment, the coating type insulating film 4b is formed so that the top surface thereof is positioned lower than a surface of the silicon substrate 2. Also, the silicon oxide film 4c is formed to cover over the coating type insulating film 4b. The coating type insulating film 4d is formed on the silicon oxide film 4c so that the bottom surface and the side surface of the coating type insulating film 4d are covered with the silicon oxide film 4c. Thus, nitrogen can be restrained by the silicon oxide film 4c from entering the coating type insulating film 4b from the silicon nitride films 7a and 7c. Consequently, the embodiment can effectively suppress an amount of fixed electric charge to a low level, which is generated in the active region Sa in the surface layer of the silicon substrate 2, and the regions B located on both sides of a portion located just under the gate insulating film 5. Accordingly, the embodiment can effectively restrain variation in the threshold value voltage of the memory cell transistors Trm.

Further, because the silicon oxide film 4c contains 5×10¹⁸ [cm³] or more of chlorine (Cl), the variation in the threshold value can be suppressed low.

### Other Embodiments

The present invention is not limited only to the aforementioned embodiments. The aforementioned embodiments can be modified or extended, for example, as follows.

The embodiments applying an aluminum oxide (Al₂O₃) film as the high-permittivity insulating film 7b have been described. However, one of a magnesium oxide (MgO) film having a relative permittivity of about 10, an yttrium oxide (Y₂O₃) film having a relative permittivity of about 16, a hafnium oxide (HfO₂) film having a relative permittivity of about 22, a zirconium oxide (ZrO2) film, and a lanthanum oxide (La₂O₃) film can be applied as the high-permittivity insulating film 7b.

Alternatively, films, such as a hafnium silicate (HfSiO) film, and a hafnium aluminate (HfAlO) film, made of ternary compounds can be applied as the high-permittivity insulating film 7b. Alternatively, films made of oxides and nitrides, which contain at least one of chemical-elements including silicon (Si), aluminum (Al), magnesium (Mg), yttrium (Y), hafnium (Hf), zirconium (Zr), and lanthanum (La), can be applied as the high-permittivity insulating film 7b.

In the aforementioned laminate structure, the silicon nitride film, the high-permittivity insulating film, and the silicon nitride film are deposited in this order from the side of the bottom layer. In the foregoing description, the embodiments, to which this laminate structure of the interelectrode insulating film 7 is applied, have been described. However, for example, a laminated structure, in which a silicon nitride film, a silicon oxide film, a high-permittivity insulating film, a silicon oxide film, and a silicon nitride film are deposited in this order from the side of the bottom layer, can be applied as that of the interelectrode insulating film 7. Alternatively, a laminate structure, in which a silicon nitride film, a silicon oxide film, a silicon nitride film, a silicon oxide film, and a silicon nitride film are deposited in this order from the side of the bottom layer, can be applied as that of the interelectrode insulating film 7.

Further, the component for generating fixed electric charges in portions positioned beside the active region located just under the gate insulating film via the element isolation insulating film in the interelectrode insulating film is not limited to nitrogen. The inventors have known that, in a case where the high-permittivity insulating film constituting the interelectrode insulating film is formed of a source including carbon, the high-permittivity insulating film can contain carbon and that the carbon contained in the high-permittivity insulating film can serve as the component for generating fixed electric charges in the portion positioned beside the active region located just under the gate insulating film. The embodiment can restrain the carbon from entering the coating type insulating film. Thus, the interelectrode insulating film can be constructed to include a laminated structure in which a silicon oxide film, a high-permittivity insulating film, and a silicon oxide film are deposited in this order from the side of the bottom layer.

Further, the nonvolatile semiconductor storage apparatus is not limited to a NAND type nonvolatile semiconductor apparatus. The other nonvolatile semiconductor storage apparatus using coating type element isolation insulating films may be realized.

Additionally, the silicon oxide films 4a and 4c formed in the element isolation insulating film 4 are not limited to monolayer films. Each of such silicon oxide films can have a laminate structure including a plurality of layers.

According to an aspect of the present invention, components contained in an interelectrode insulating film and adapted to generate fixed electric charges can be restrained from being diffused into a part located beside an active region immediately under a gate insulating film through a coating type element isolation insulating film. Also, the electric characteristic of a device can be prevented from being deteriorated.

What is claimed is:

1. A nonvolatile semiconductor storage apparatus comprising:
a semiconductor substrate on which element isolation trenches are formed to define element formation regions on the semiconductor substrate;
gate insulating films that are formed on the element formation regions of the semiconductor substrate;
floating gate electrodes that are formed on the gate insulating films;
element isolation insulating films that each comprises:
a coating type insulating film that is formed in a corresponding one of the element isolation trenches; and
a non-coating type insulating film that is formed to cover a top surface of the coating type insulating film;
a interelectrode insulating film that is formed on the element isolation insulating films and floating gate electrodes; and
a control gate electrode that is formed on the interelectrode insulating film.

2. The nonvolatile semiconductor storage apparatus according to claim 1,
wherein the element isolation insulating films are formed to protrude from the semiconductor substrate.

3. The nonvolatile semiconductor storage apparatus according to claim 1,
wherein the non-coating type insulating film includes a silicon oxide film.

4. The nonvolatile semiconductor storage apparatus according to claim 1,
wherein the non-coating type insulating film includes a silicon oxide film that contains 5×10¹⁸ [atoms·cm⁻³] or more of chlorine.

5. The nonvolatile semiconductor storage apparatus according to claim 1, wherein the non-coating type insulating film has a density equal to or more than 2.2 [g·cm⁻³].

6. The nonvolatile semiconductor storage apparatus according to claim 1,
wherein the non-coating type insulating film prevents nitrogen contained in the interelectrode insulating film form entering into the coating type insulating film.

7. The nonvolatile semiconductor storage apparatus according to claim 1,
wherein the non-coating type insulating film includes a silicon oxide film into which a chemical-element having a high electronegativity is introduced.

8. The nonvolatile semiconductor storage apparatus according to claim 1,
wherein the non-coating type insulating film includes a polysilazane-based spin-on glass film.

9. The nonvolatile semiconductor storage apparatus according to claim 1,
wherein the coating type insulating film is formed so that a top surface of the coating type insulating film is positioned lower than a top surface of the floating gate electrodes.

10. The nonvolatile semiconductor storage apparatus according to claim 1,
wherein the coating type insulating film is formed so that a top surface of the coating type insulating film is positioned lower than a top surface of the floating gate electrodes and higher than a bottom surface of the floating gate electrodes.

11. The nonvolatile semiconductor storage apparatus according to claim 1,
wherein the coating type insulating film is formed so that a top surface of the coating type insulating film is positioned lower than a bottom surface of the floating gate electrodes.

12. The nonvolatile semiconductor storage apparatus according to claim 1,
wherein the interelectrode insulating film includes a silicon nitride film.

13. The nonvolatile semiconductor storage apparatus according to claim 1,
wherein the interelectrode insulating film includes a dielectric film having a relative permittivity of 8 or more.

14. The nonvolatile semiconductor storage apparatus according to claim 1,
wherein the interelectrode insulating film includes one of:
an aluminum oxide film;
a magnesium oxide film;
an yttrium oxide film;
a hafnium oxide film;
a zirconium oxide film; and
a lanthanum oxide film.

15. The nonvolatile semiconductor storage apparatus according to claim 1,
wherein the interelectrode insulating film includes one of:
a hafnium silicate film; and
a hafnium aluminate film.

16. The nonvolatile semiconductor storage apparatus according to claim 1,
wherein the interelectrode insulating film includes one of:
an aluminum nitride film;
a magnesium nitride film;
an yttrium nitride film;
a hafnium nitride film;
a zirconium nitride film; and
a lanthanum nitride film.

17. A nonvolatile semiconductor storage apparatus comprising:
a semiconductor substrate on which an element isolation trench is formed to define an element formation region;
an element isolation insulating film that has a lower portion buried in the element isolation trench and an upper portion protruding from a surface of the semiconductor substrate;
a gate insulating film that is formed on the element formation region and that has a side surface contacting a side surface of the upper portion of the element isolation insulating film;
a floating gate electrode that is formed on the gate insulating film and that has a top surface, a lower side surface contacting the side surface of the upper portion of the element isolation insulating film, and an upper side surface located above the lower side surface;
an interelectrode insulating film that is formed along a top surface of the element isolation insulating film, the upper side surface of the floating gate electrode, and the top surface of the floating gate electrode; and
a control gate electrode that is formed on the interelectrode insulating film,
wherein element isolation insulating film includes:
a coating type insulating film that is formed in the element isolation trench; and
a silicon oxide film that is formed to cover a top surface of the coating type insulating film and to isolate the coating type insulating film from the interelectrode insulating film, and
wherein silicon oxide film contains 5×10¹⁸ [atoms·cm⁻³] or more of chlorine.

18. A method for manufacturing a nonvolatile semiconductor storage apparatus, the method comprising:
forming a gate insulating film on a semiconductor substrate;
forming a floating gate electrode film on the gate insulating film;
defining an active region on the semiconductor substrate by forming an element isolation trench to divide the floating gate electrode film, the gate insulating film, and an upper portion of the semiconductor substrate;
forming a coating type insulating film in the element insulation trench;
forming a silicon oxide film containing 5×10¹⁸ [atoms·cm⁻³] or more of chlorine so as to cover a top surface of the coating type insulating film by use of a chlorine-contained gas;
forming an interelectrode insulating film along a top surface of the silicon oxide film, a side surface of the floating gate electrode film, and a top surface of the floating gate electrode film; and
forming a control gate electrode film on the interelectrode insulating film.
